(19) United States
(12) Patent Application Publication
(10) Pub. No.: US 2008/0018353 A1
(43) Pub. Date: Jan. 24, 2008

(54) Methods and apparatus for releasably mounting a semiconductor device to a printed circuit board

(76) Inventor: Francis Rapheal Thamarayoor, Bangalore (IN)

Correspondence Address: TEXAS INSTRUMENTS INCORPORATED, P O BOX 655474, M/S 3999, DALLAS, TX, 75265, US

(21) Appl. No.: 11/491,871

(22) Filed: Jul. 24, 2006

(51) Int. Cl. G01R 31/26

(52) U.S. Cl. 324/765

(57) ABSTRACT

Methods and apparatus for releasably mounting a semiconductor device, such as a ball grid array (BGA) integrated circuit to a printed circuit board (PCB) are disclosed. The socket includes a base mountable over a contact pad of the printed circuit board and having an opening to receive the semiconductor device. A socket board is mountable to or integrally formed with the base. The socket board includes at least one aperture having a spring contact for electrically coupling a contact element of the semiconductor device to a contact of the printed circuit board when the semiconductor device is received in the base.

### FIELD OF THE DISCLOSURE

The present disclosure relates generally to integrated circuits and, more particularly, to methods and apparatus for releasably mounting a semiconductor device to a printed circuit board.

### BACKGROUND

Sockets are typically used in test printed circuit boards (PCBs) for testing and/or certifying integrated circuits (ICs), or in assembled PCB's where an IC needs to be replaced. In some instances, it may be desirable to test multiple integrated circuits on each test PCB, thereby avoiding the need to make multiple PCBs. For example, each integrated circuit may be temporarily mounted to the test PCB via a respective socket. An integrated circuit may include a plurality of contacts including a group of solder dots or balls arranged to connect to a circuit board. Such a contact arrangement is commonly known as a ball grid array (BGA).

Some prior art sockets utilize pogo pins to electrically connect the BGA to the test PCB. In general, pogo pins are contacts that electrically couple the balls of the BGA device to the conductors on the main PCB. A pogo pin includes an elongated, vertically arranged, cylindrical tube that includes a gold-plated crown on one end to contact the solder balls of the BGA device, and a pin at the other end, to contact a female conductor or pad on the main PCB. Both the crown and the pin are loaded by one of more springs located in the cylindrical housing such that the crown and pin are bound away from one another and away from the housing. The pogo pins are usually held by insulators housed in the socket to electrically isolate each pogo pin.

In use, the contacts of the BGA device (e.g., solder balls) rest upon the crowns of the pogo pins, pushing them against the spring forms and into electrical communication with the female conductors or pads on the main PCB. A socket lid holds the BGA device (e.g., an IC) in engagement with the socket against the spring forms of the pogo pins. Depending upon various conditions, the crown may cause minute deformations in the BGA contact, leading to possible problems during final assembly. Furthermore, pogo pins exhibit relatively high inductance, which may impede tests of high frequency ICs.

Another prior art example socket utilizes a membrane between the BGA device and the PCB instead of pogo pins. Tiny metal dots are equally spaced on an insulated membrane, and the membrane is supported above the PCB so as to not contact any of the conductors. The BGA is then placed over the membrane and biased toward the membrane and PCB, forcing a group of the metal dots toward the PCB, and into electrical contact with one of the PCB conductors or pads. Although membrane base sockets are lower cost than pogo pins and sockets, membrane sockets may not achieve reliable contact between the BGA device and the PCB conductors because of contact drift, and/or misalignment.

### SUMMARY

Certain examples of the disclosure may provide one or more technical advantages. For instance, a technical advantage of at least one example is a reduction in manufacturing costs. In particular, in one example, known printed circuit board manufacturing techniques may be utilized to manufacture the disclosed socket, thereby reducing specialized manufacturing requirements. Another technical advantage may be that the disclosed socket can be used at higher frequencies because the inductance of the contact is less than known sockets, for example, pogo pin type sockets. Still another technical advantage may be that the socket may accommodate BGA connections of differing size, allowing for larger manufacturing tolerances. Yet another technical advantage may be that the contact reduces damage to the BGA connections of the integrated circuit by reducing the force required to mount the IC to the socket.

In accordance with an example, an apparatus may be used for electrically mounting a semiconductor device to a substrate with a process control device. The example apparatus includes a base mountable to the substrate to receive the semiconductor, and a socket board mounted within an opening of the base. The socket board includes at least one aperture and a leaf spring contact extending at least partially across the aperture to electrically couple the semiconductor device to the substrate.

In accordance with another example, a socket assembly mountable to a printed circuit board is disclosed. The example assembly includes an integrated circuit having an electrical contact, a substrate having a via hole through the substrate, and a flexible contact at least partially occluding the via hole. The flexible contact is shiftable to form an electrical path between the electrical contact on the integrated circuit and the printed circuit board.

In accordance with another example, a method of mounting an integrated circuit on a substrate is disclosed. The method comprises inserting the integrated circuit into an opening defined in a socket such that a solder ball of a BGA of the integrated circuit engages a leaf spring carried by the socket, and displacing the leaf spring into engagement with the contact pad to form a conductive path between the solder ball, the leaf spring, and the conductive pad.

In accordance with another example, a method of manufacturing a socket for mounting an integrated circuit is disclosed. The method includes forming a via hole in a socket board, mounting a leaf spring to the socket board to at least partially occlude the via hole, and mounting the socket board to a base having an opening to receive the integrated circuit. The socket board is mounted within the opening of the base a distance above the bottom surface, the distance being less than a length of the leaf spring.

Other technical advantages may be readily apparent to one skilled in the art from the figures, descriptions, and claims included herein. None, some, or all of the examples may provide technical advantages.

### BRIEF DESCRIPTION OF THE DRAWINGS

FIG. 1 is an exploded front perspective assembly view of an example socket assembly for releasably mounting a semiconductor device to a printed circuit board.

FIG. 2 is a cross sectional view of the socket assembly of FIG. 1 taken along line 2-2.

FIG. 3 is an enlarged cross sectional view of an example spring contact area of the example socket assembly of FIG. 1, showing a ball of a grid array device being inserted and/or removed from the PCB.

FIG. 4 is an enlarged cross sectional view similar to FIG. 3, but showing the ball grid array device mounted to the PCB.

FIG. 5 is a top plan view of the example spring contact area of FIG. 3.

FIG. 6 is a plan view of another example socket board for use with the socket assembly of FIG. 1.

FIG. 7 is a side elevational view of an example spring contact of the socket board of FIG. 6.

FIG. 8 is a plan view of an example assembly for releasably mounting a daughter board to a mother board.

FIG. 9 is cross-sectional view of the example assembly of FIG. 8 taken along line 9-9.

### DETAILED DESCRIPTION

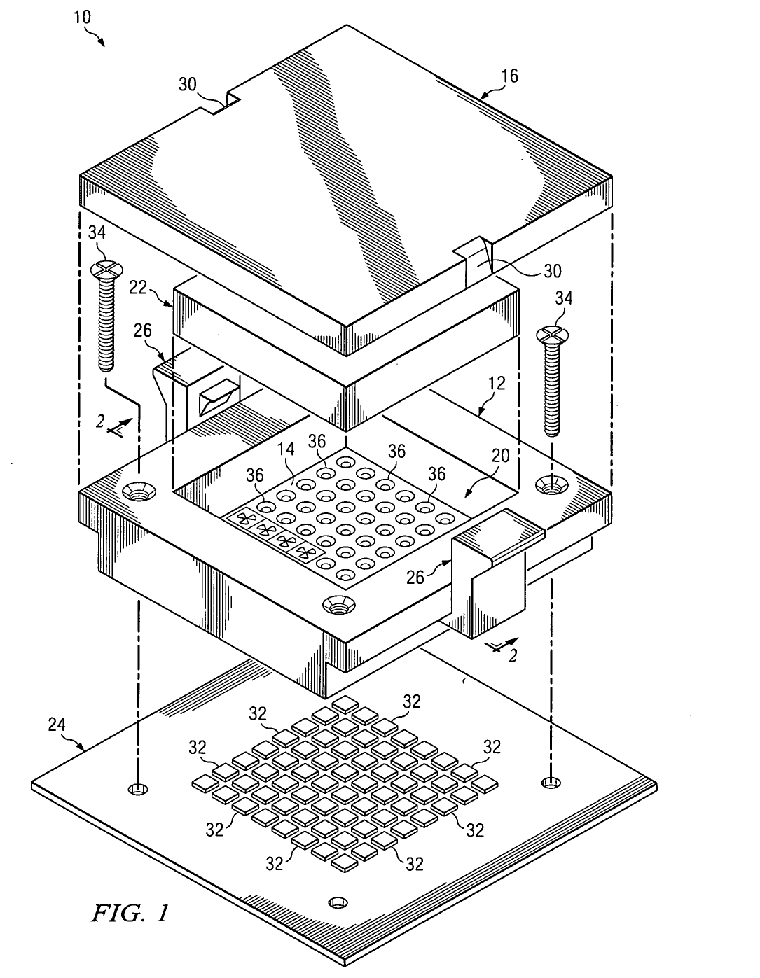

Referring now to FIG. 1, an example socket assembly 10 is shown in perspective view. In this example, the assembly 10 includes a base 12, and a socket board 14 mounted to, or integrally formed with the base 12. The base 12 includes a cavity or opening 20 sized to receive a semiconductor device such as an integrated circuit (IC) 22. The entire assembly 10 may be mounted to a target, such as for example, a printed circuit board (PCB) 24. Thus, the example socket 10 of FIG. 1 is will suited for mounting an IC to a test PCB for testing of the IC. The example assembly 10 illustrated in FIG. 1 may optional include a socket lid 16 which may be releasably mounted to the base 12 by, for example, an arm 26 and a retaining surface 30 cooperating to form a press-fit connection, to secure the lid in the base 12. It will be appreciated that the socket lid 16 may be releasably mounted to the base 12 by any suitable method, including, for instance, clamping, gluing, screwing, fastening, etc.

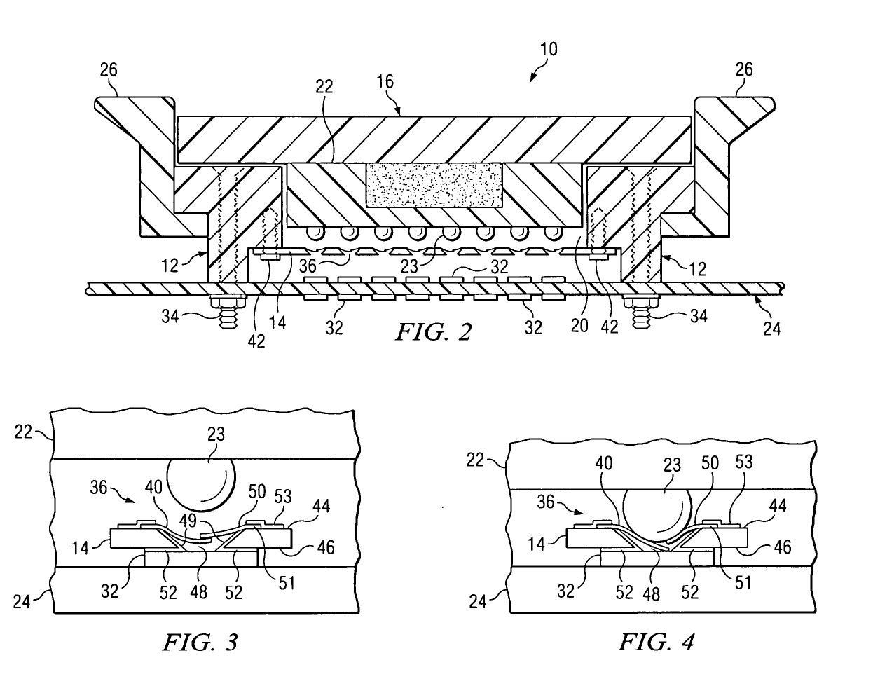

The example socket 10 of FIG. 1 is particularly well suited for securing ICs having a ball grid array. Thus, semiconductor device 22 to be coupled to the example socket 10 will include at least one contact element 23 (see FIG. 2), such as a solder dot or ball of a ball grid array, a pin, a pad, etc.

In the illustrated example, the PCB 24 is implemented by a main verification development board, for testing ICs. However, other types of PCBs could alternatively be employed. The PCB 24 of the illustrated example includes a plurality of spaced apart contacts 32, such as contact pads, electrically coupled to various other components of the PCB 24. The example socket assembly 10 may be permanently or removably mounted to the PCB 24 by any suitable attachment mechanism, including for example, by press-fitting, soldering, gluing, clamping, fastening, etc. In the illustrated example, the socket base 12 and the PCB 24 are mounted via a plurality of removable screw fasteners 34 which also act as an alignment device to aid in the proper alignment of the socket assembly 10 with the PCB 24.

The socket board 14 of the illustrated example includes a substrate 14 made of a generally non-conductive material, however, the substrate 14 may be constructed of any suitable material, including, for example, another printed circuit board. A plurality of spaced apart spring contact areas 36 are mounted with the substrate 14 in a pattern corresponding to the BGA of the IC to be received by the socket 10. An example spring content area 36 is illustrated in detail in FIGS. 3-5. In general, each of the spring contact areas 36 is located to align over a corresponding contact pad 32 of the target PCB 24. The socket board 14 of the illustrated example may be permanently or removably mounted to the socket base 12 by any suitable attachment method such as, for example, via a plurality of removable screw fasteners 42.

An enlarged view of an example spring contact area 36 of the example socket board 14 is illustrated in FIGS. 3-5. In particular, the socket board 14 of the illustrated example includes an upper surface 44 facing away from the PCB 24, and a lower surface 46 facing toward the PCB 24. The example socket board 14 includes a via hole or aperture 48 extending between the upper surface 44 and the lower surface 46 in the contact area 36. In this example, the aperture 48 includes a chamfered surface 49 connecting the upper and lower surfaces 44, 46, but it will be appreciated by persons of ordinary skill in the art that any geometry may be used for the surface 49. The aperture 48 may be formed by any suitable manufacturing technique, including, for example, by taper drilling the PCB 24.

In this example, the aperture 48 is at least partially occluded by a spring contact 40. In particular, the spring contact 40 extends substantially horizontally from the first surface 44 across the aperture 48 past the center of the aperture 48 to partially occlude the aperture 48. The spring contact 40 of the illustrated example is implemented by a flexible, conductive material, such as a phosphor bronze metal or copper, and/or other spring material. Additionally, the spring contact 40 of the illustrated example bends when subjected to a force less than the force required to deform the surface of the contact elements 23, thereby assisting in reducing possible damage to the contact elements 23 when mounting the corresponding IC in the example socket 36.

As illustrated in FIG. 3, the IC 22 is separated from the base 12, and the spring contact 40 is biased away from the target PCB 24 and toward the plane generally defined by the upper surface 44 of the socket board 14, such that the spring contact 40 does not intersect the plane generally defined by the lower surface of the socket board 14. In contrast, as illustrated in FIG. 4, when the IC 22 is mounted in the example socket 10, the contact element 23 forces the spring contact 40 away from the plane generally defined by the upper surface 44 of the socket board 14, and toward the plane generally defined by the lower surface 46 of the socket board 14, such that the spring contact 40 contacts the contact pad 32 of the PCB 24.

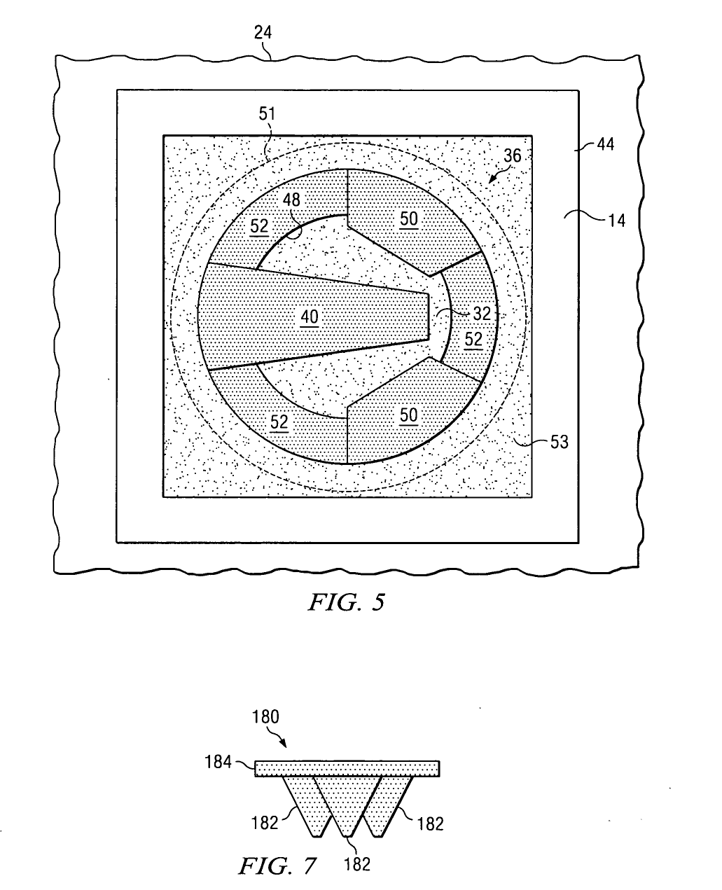

In the illustrated example, the spring contact area 36 comprises a plurality of leaf springs 50, such as, for example, foil springs. The leaf springs 50, together with the spring contact 40, provide an upwardly directed force on the ball 23 to assist in removing the corresponding IC from the socket 10, when desired. The leaf springs 50 may be electrically coupled by a pad (shown in phantom in FIG. 5) or other electrical coupling, or may be electrically isolated from one another, if desired. In this example, only the leaf springs 50 and the spring contact 40 are exposed, the other areas are covered with a solder mask 53 or other insulating material to electrically isolate and/or reinforce the leaf springs 50 and/or the spring contact 40. Additionally, the size, number, and shape of the spring contact 40 and/or the leaf springs 50 may vary from that illustrated. For example, in the illustrated example, the spring contact 40 is longer than the leaf springs 50. However, the leaf springs 50 and the spring contact 40 may alternatively be symmetrical in size and/or shape. It will be appreciated that the length of the spring contact 40 and/or the length(s) of the leaf springs 50 may be selected in order to reduce the induction of the electrical path formed between the contact element 23 and the contact pad 32. Accordingly, all, some, or none of the leaf springs 50 and/or the spring contact 40 may contact the contact pad 32 when the IC 22 is received in the base 12 of the socket 10. The leaf spring 50 may be made of the same or different material as the spring contact 40.

In the example of FIGS. 3-5, solder mark 52 is positioned over portion of the spring contact 40 and the leaf springs 50. The spring contact 40 and leaf springs 50 can be secured to the upper surface of the socket substrate 14 via epoxy or other fastener. The solder mask 53 insulates the ends of the spring contact 40 and the leaf springs 50 such that only the portion of the spring contact 40 and leaf springs 50 that extend into the aperture 48 are exposed to electrical contact from above.

In the illustrated example, the surface 49 of the aperture 48 includes a conductive plating 52 along at least a portion thereof. As shown in FIGS. 3 and 4, the conductive plating 52 extends over the surface 49, and over a portion of the lower surface 46. Accordingly, the conductive plating 52 forms a conductive pathway between the spring contact 40, and the contact pad 32, and a conductive path between each leaf springs 50 and the conductive pad 32, thereby electrically coupling the contact element 23 to the contact pad 32 of the PCB 24. In this manner, the conductive plating 52 may provide an additional, backup, and/or only (in the case where neither the spring contact 40 or the leaf springs 50 contact the contact pad 32) electrical path(s) between the contact element 23 and the contact pad 32. Accordingly, the aperture 48 may accommodate and/or correct for variations in the size of the contact element 23, and/or improper seating of the contact elements 23 within the aperture 48 while maintaining an electrical path between the contact element 23 and the contact pad 32.

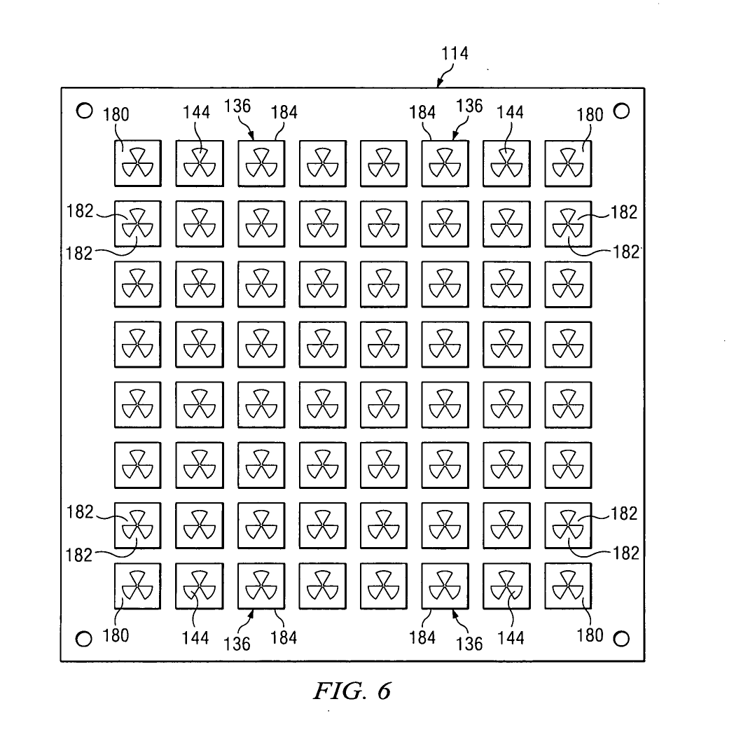

Another example socket board 114 is shown in FIG. 6. In this example, a socket board 114 includes a plurality of spaced apart spring contact areas 136. Each of the spring contact areas includes a via hole or aperture 144 and a spring contact 180. Each spring contact 180 has a plurality of fingers 182, electrically coupled by a spring base 184 and adapted to at least partially occlude the corresponding aperture 144. As shown in detail in FIG. 6, the fingers 182 extend readily inward from the spring base 184 and into the aperture 144. Each of the spring contacts 180 includes three symmetrically sized and spaced fingers 182, although, any number and shape of fingers 182 may be used. Furthermore, the spring contact 180 may be made of any suitable conductive material or materials and may be manufactured by any known or yet to be developed manufacturing technique, including, for example, laser cutting, printed circuit board manufacturing techniques, such as etching and/or laminating conductive and/or non-conductive substrates.

In one example, the socket 10 may be manufactured by forming the aperture 48 in a socket board 14, by, for example, taper drilling of the substrate, or other suitable technique, such as punching and/or die cutting. The leaf springs 50 and/or spring contact 40, may be mounted to the socket board 14 to at least partially occlude the aperture 48. It will be appreciated by persons of ordinary skill in the art that the mounting of the leaf springs 50 and/or the spring contact 40 may occur prior to, during, or after the formation of the aperture 48. The socket board 14 may be mounted, or integrally formed with the base 12, and further mounted to the PCB 24 such that the aperture 48 is located above the contacts 32 of the PCB 24 and the leaf springs 50, and/or the spring contact 40 is engageable with the contact 32 when displaced by the IC 22.

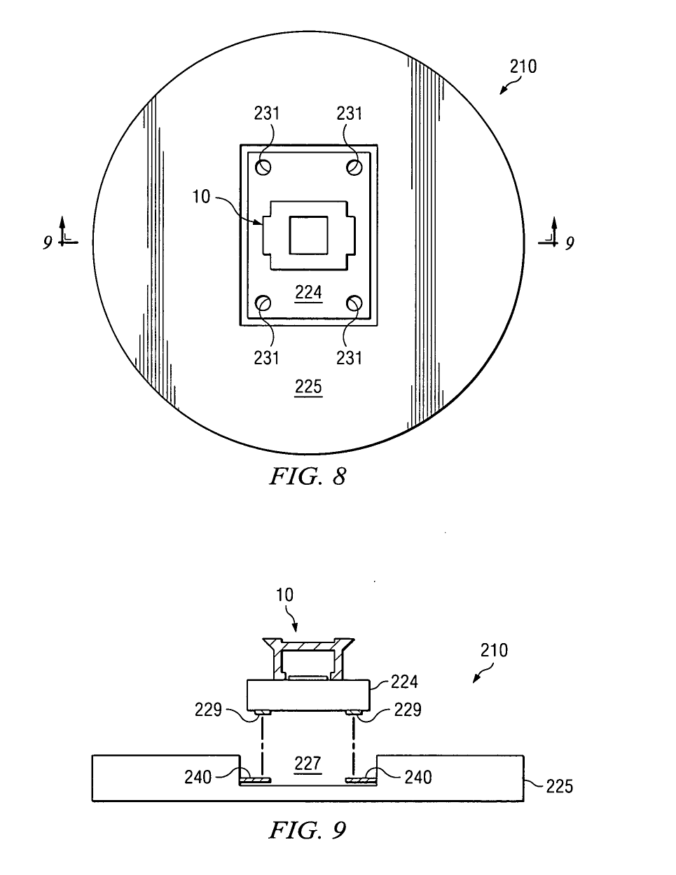

Another example assembly 200 is shown in FIGS. 8 and 9. In this example, the assembly 210 includes the socket assembly 10 mounted to the PCB 24. For example, in this assembly 210, the PCB 24 of the socket assembly 10 is a daughter board 224 mountable to a mother board 225. The example daughter board 224 includes, on its bottom surface, a plurality of contacts, such as, for example, contact pads 229. Further, the daughter board 224 of the illustrated example may include at least one aperture 231 for receiving a removable fastener (not shown) to mount the daughter board 224 to the mother board 225, and to assist in the alignment of the daughter board 224 to the mother board 225.

The example mother board 225 includes a cavity or opening 227 sized to receive the daughter board 224. In this example, the opening 227 is at least partially occluded by a plurality of flexible contacts, such as leaf spring contacts 240. In particular, the leaf spring contacts 240 extend substantially horizontally from mother board 225 across the opening 227. An example leaf spring contact 240 of the illustrated example is implemented by a flexible, conductive material, such as a phosphor bronze metal or copper, and/or other spring material. To electrically couple the daughter board 224 to the mother board 225, the daughter board 224 is brought into proximity to the mother board 225 such that each the contact pads 229 press against a corresponding leaf spring contact 240, thereby forming an electrical path through the contact pads 229 and leaf spring contact 240.

From the foregoing, persons of ordinary skill in the art will appreciate that low cost sockets for mounting, for example, BGA devices to PCBs have been disclosed. The illustrated example sockets 10 are easily manufacturable using PCB manufacturing technology. The illustrated sockets 10 are more reliable than prior art membrane sockets and less expensive than prior art pogo pin sockets. Further, because the solder balls of the BGA device are seated on respective springs 40, 50, 182, differences in the diameter of the solder balls are automatically accommodated by the sockets 10. Further, because the high inductance of the pogo pins is eliminated, the example contacts of the sockets 10 herein have lower inductance than pogo pin sockets and, thus, better accommodate high frequency signals.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

We claim:

1. An apparatus for mounting a semiconductor device having a first contact element to a substrate having a second contact element, comprising:
a base mountable to the substrate and defining an opening to receive at least a portion of the semiconductor device; and
a socket board mounted within the opening, the socket board defines at least one aperture and a leaf spring contact extending at least partially across the aperture to electrically couple the first contact element of the semiconductor device to the second contact element of the substrate.

2. An apparatus as defined in claim 1, wherein the leaf spring contact is biased away from the substrate such that the leaf spring contact does not contact the second contact element when the semiconductor device is removed from the base.

3. An apparatus as defined in claim 1, further comprising a socket lid mountable to the base to secure the semiconductor in the base.

4. An apparatus as defined in claim 3, wherein each of the base and the socket lid include one of an extension or a detent that cooperate to releasably secure the socket lid to the base.

5. An apparatus as defined in claim 1, wherein the aperture includes a conductive plating electrically coupling the leaf spring contact to the second contact element of the target.

6. An apparatus as defined in claim 1, wherein the leaf spring contact is a foil spring.

7. An apparatus as defined in claim 1, wherein the leaf spring includes at least two leaf springs.

8. An apparatus as defined in claim 1, wherein the socket board includes a first surface facing away from the substrate, and a second surface facing the substrate, the leaf spring contact being mounted to the first surface.

9. An apparatus as defined in claim 1, further comprising an alignment device to align the base with the substrate.

10. An apparatus as define din claim 1, wherein the semiconductor device is a ball grid array device.

11. An apparatus as defined in claim 1, wherein the spring contact extends from a first side of the aperture past a center of the aperture.

12. An apparatus as defined in claim 11, further comprising at least one leaf spring on a second side of the aperture.

13. An apparatus as defined in claim 12, wherein the at least one leaf spring has a length less than a length of the spring contact.

14. An apparatus as defined in claim 1 wherein the spring contact comprises a plurality of spring fingers.

15. An apparatus as defined in claim 14, wherein the spring fingers extend radially toward the center of the aperture.

16. An apparatus as defined in claim 15, wherein the spring fingers have substantially the same length.

17. A socket assembly mountable to a printed circuit board comprising:
an integrated circuit having an electrical contact;
a substrate having a first surface and a second surface opposite the first surface, and a via hole extending through the substrate between the first surface and the second surface; and
a substantially horizontally dispose flexible socket contact mounted on the first surface and at least partially occluding the via hole, the flexible socket contact being shiftable towards the second surface to form an electrical path between the electrical contact on the integrated circuit and the printed circuit board.

18. A socket as defined in claim 17, wherein the via hole includes a conductive surface extending between the flexible socket contact and the printed circuit board.

19. A socket as defined in claim 17, wherein the flexible socket contact comprises a plurality of leaf springs.

20. A socket as defined in claim 17, wherein the printed circuit board includes a plurality of contacts and wherein the socket assembly further comprises a second printed circuit board having an opening sized to receive the printed circuit board and having a plurality of contacts corresponding to the contacts of the printed circuit board, such that the printed circuit board is electrically coupled to the second printed circuit board when the printed circuit board is mounted in the opening of the second printed circuit board.

21. A socket as defined in claim 20, wherein the plurality of contacts of the second printed circuit board comprises at least one spring contact extending at least partially across the opening.

22. A method of mounting an integrated circuit on a substrate, the substrate including a contact pad, the method comprising:
inserting the integrated circuit into an opening defined in a socket such that a solder ball of a BGA of the integrated circuit engages a leaf spring carried by the socket; and
displacing the leaf spring into engagement with the contact pad to form a conductive path between the solder ball, the leaf spring and the conductive pad.

23. A method as defined in claim 22, further comprising securing a lid to the socket to retain the integrated circuit in the socket.

24. A method as defined in claim 22, wherein displacing the leaf spring comprises securing a lid to the socket to retain the integrated circuit in the socket.

25. A method as defined in claim 22, further comprising mounting the socket to the substrate.

26. A method as defined in claim 22, wherein the socket includes a base mounted on the substrate, and a socket board defining an aperture, the leaf spring being mounted in the aperture above the solder pad.

27. A method of manufacturing a socket for mounting an integrated circuit to a printed circuit board, the method comprising:
forming a via hole in a socket board;
mounting a leaf spring to the socket board to at least partially occlude the via hole;
mounting the socket board to a base, the base having a bottom surface and defining a through opening to receive the integrated circuit, the socket board being mounted within the opening a distance above the bottom surface, the distance being less than a length of the leaf spring.

28. A method as defined in claim 27, further comprising mounting the socket to the printed circuit board such that the via hole is located above a conductive pad of the circuit board and the leaf spring is engageable with the conductive pad when displaced by the integrated circuit.

29. A method as defined in claim 27, further comprising mounting an integrated circuit to the socket board to displace the leaf spring at least partially through the via hole.
